(19) United States
(12) Patent Application Publication
(10) Pub. No.: US 2012/0268869 A1
(43) Pub. Date: Oct. 25, 2012

(54) ELECTRONIC DEVICE ENCLOSURE

(75) Inventor: GANG-QIANG QIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/431,980

(22) Filed: Mar. 28, 2012

(30) Foreign Application Priority Data
Apr. 22, 2011 (CN) 201110101748.7

(51) Int. Cl. H05K 5/00

(52) U.S. Cl. 361/679.01

(57) ABSTRACT

An electronic device enclosure includes a top plate and a cover. The top plate defines an opening. The top plate includes a supporting member and a plurality of securing members around the supporting member. The supporting member is located on edges of the opening and surrounding the opening. The cover is covered on the supporting member and secured to the plurality of securing members, to separate the opening from outdoor.

### BACKGROUND

1. Technical Field

The present disclosure relates to electronic device enclosures, more particularly to an electronic device enclosure for data center servers.

2. Description of Related Art

Blade and rack-mounted servers are popular form factors for data center servers. In order to achieve high performance, many rack-mounted servers are clustered in an enclosure. The enclosure includes a top plate, and a cooling device, adjacent to the top plate, is received in the enclosure for cooling the servers. An opening is defined in the top plate. When the cooling device needs to maintain, the cooling device can be in or out of the enclosure via the opening. However, when water flows onto the enclosure, water may flow into the interior of the data center servers from the openings. Thus, the servers can be damaged with the moisture.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device enclosure in accordance with an embodiment.

FIG. 2 is an exploded, cut-away view of FIG. 1, and a mounting gasket of FIG. 1 is detached from an enclosure of FIG. 1.

FIG. 3 is an enlarged view of a circled portion III of FIG. 2.

FIG. 4 is similar to FIG. 2, but the mounting gasket is mounted to the enclosure.

FIG. 5 is an enlarged view of a circled portion V of FIG. 2.

FIG. 6 is an assembled view of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

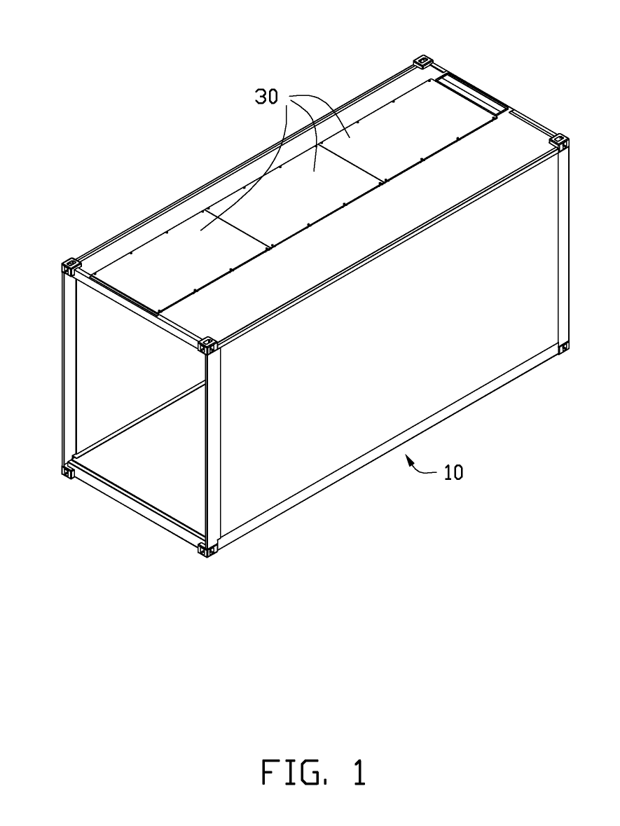

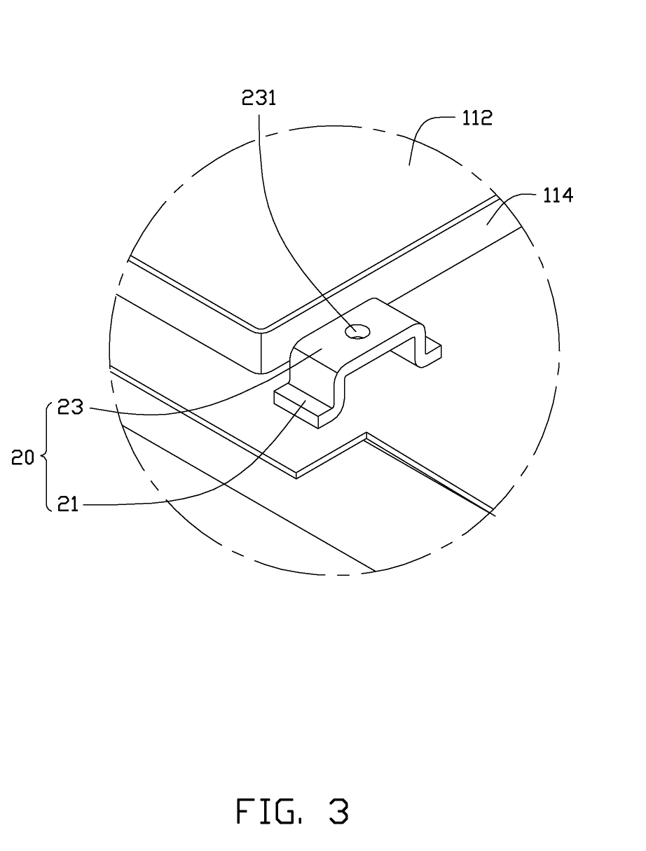

Referring to FIGS. 1-3, an electronic device enclosure in accordance with an embodiment is an enclosure 10. The enclosure 10 includes a top plate 11, three covers 30 attached to the top plate 11, and three mounting gaskets 50 attached to the three covers 30. In one embodiment, the enclosure 10 is a container for receiving blade and rack-mounted servers.

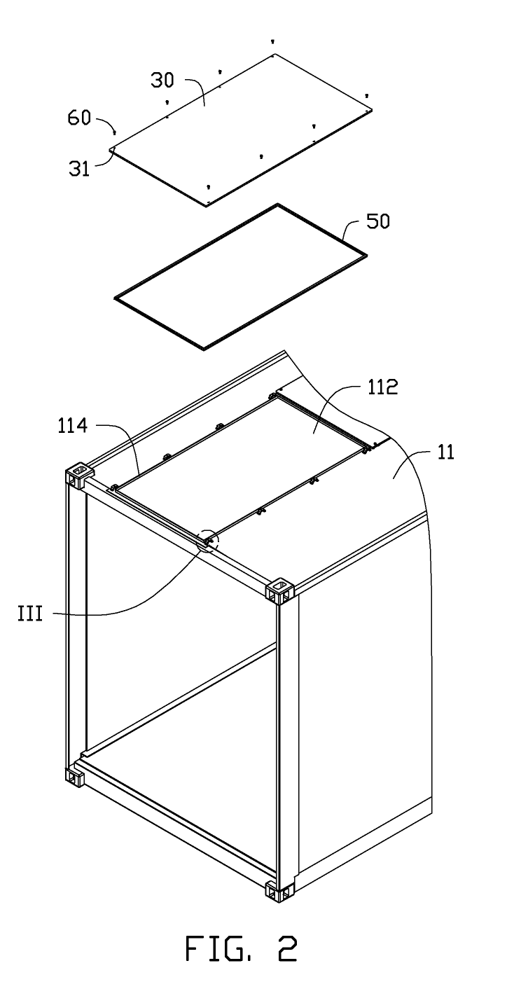

Three openings 112 (only one shown in FIG. 2) are defined in the top plate 11, and a supporting member 114 surrounds on each opening 112. In one embodiment, the supporting member 114 includes four supporting flanges connected to the four edges of the openings 112. A plurality of securing members 20, adjacent to the supporting member 114, is located on the top plate 11. Each securing member 20 includes two securing portions 21, and a securing bridge 23 connected to the two securing portions 21. A securing hole 231 is defined in the securing bridge 23. In one embodiment, the opening 112 is a rectangle, the supporting member 114 is substantially perpendicular to the top plate 11, and a height between the securing bridge 23 and the top plate 11 is greater than that of the supporting member 114.

A plurality of mounting holes 31 is defined in each of the three covers 30 and corresponds to the plurality of securing holes 231. In one embodiment, each of the three covers 30 is a rectangle.

Each of the three mounting gaskets 50 is located between the each of three supporting members 114 and each of the three covers 30. In one embodiment, the mounting gasket 50 is made of plastic, and a length and a width of the mounting gasket 50 is greater than that of the opening 112.

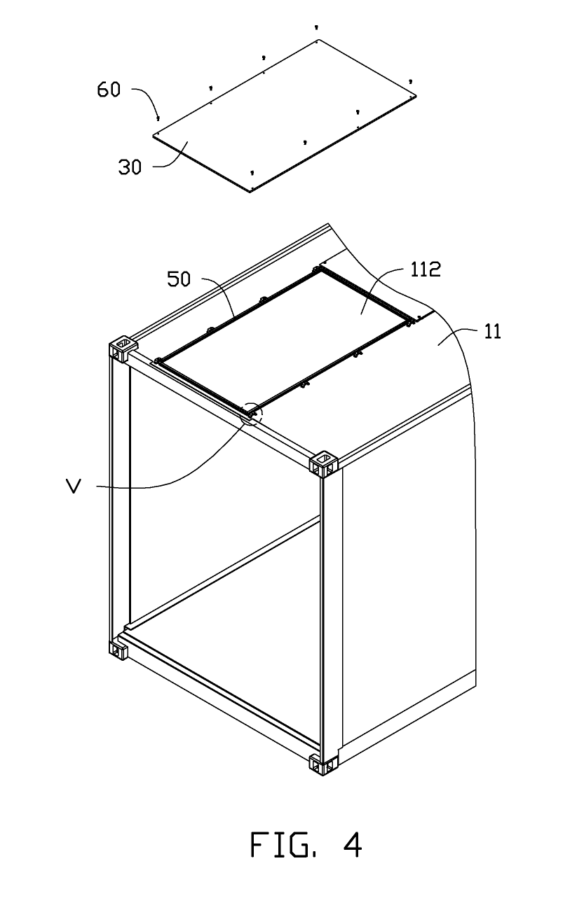

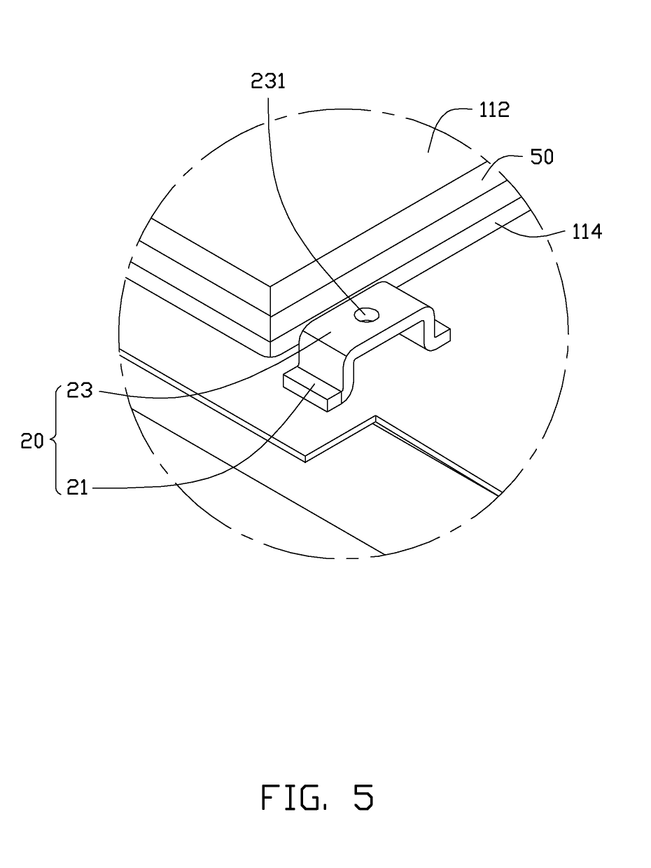

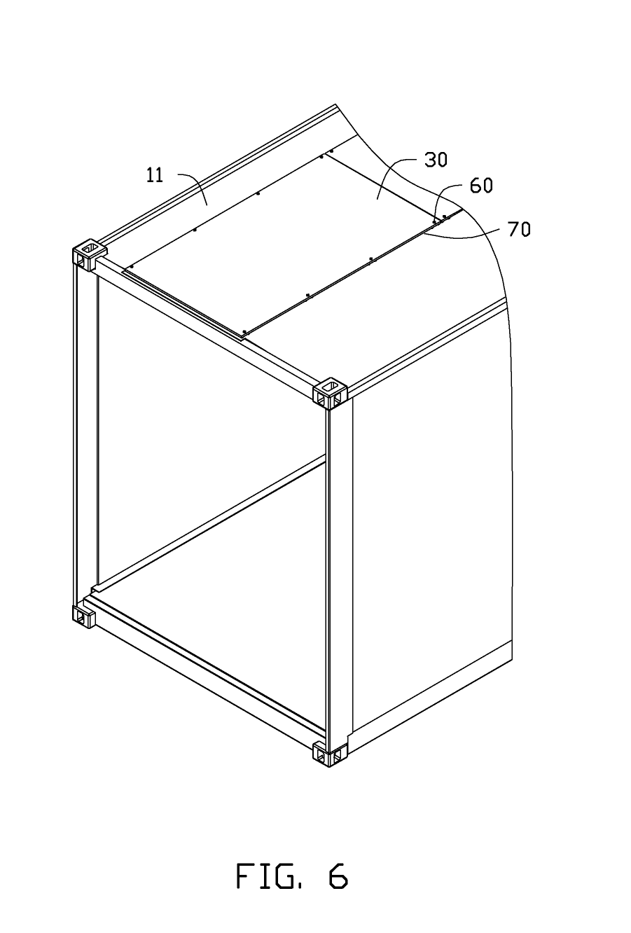

Referring to FIGS. 4-6, the mounting gasket 50 is attached to the supporting member 114. The cover 30 is attached to the mounting gasket 50. The plurality of mounting holes 31 is aligned with the plurality of securing holes 231. A plurality of fixing members 60 are engaged in the plurality of mounting holes 31 and securing holes 231, and the cover 30 is secured to the plurality of securing members 20. A gap 70 (see FIG. 6) is defined between the cover 30 and the top plate 11.

When a cooling device (not shown) in need of maintenance, the fixing members 60 are removed from the plurality of mounting holes 31 and securing holes 231, to detach the cover 30 from the top plate 11. Therefore, the cooling device can be moved from the enclosure 10 via the opening 112.

In addition, because the length and width of the cover 30 is greater than that of the opening 112, when water flows onto the top plate 11 and the cover 30, water can flow into the gap 70 along the four edges of the cover 30, and further flows out of the enclosure 10 via the top plate 11. The mounting gasket 50 is located between the supporting member 114 and the cover 30, to shield a gap between the supporting member 114 and the cover 30. Thus, water cannot flow into the enclosure 10 from the gap between the supporting member 114 and the cover 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a top plate defining an opening, and the opening having a first width; the top plate comprising a supporting member located on edges of the opening and surrounding the opening; and the supporting member comprising a plurality of supporting flanges substantially perpendicular to the top plate; and
a cover; the cover having a second width, the second width being greater than the first width;
wherein the cover is attached to the supporting member, to separate the opening from outdoor.

2. The electronic device enclosure of claim 1, wherein the opening further has a first length, and the cover has a second length greater than the first length.

3. The electronic device enclosure of claim 1, further comprising a mounting gasket, and the mounting gasket is located between the supporting member and the cover.

4. The electronic device enclosure of claim 3, wherein the mounting gasket has a size greater than that of the supporting member, and the mounting gasket covers on an upper portion of the supporting member.

5. The electronic device enclosure of claim 3, wherein the mounting gasket is made of plastic.

6. The electronic device enclosure of claim 1, wherein the top plate further comprises a plurality of securing members around the supporting member, and the plurality of securing members is secured to the cover.

7. The electronic device enclosure of claim 6, wherein each of the plurality of securing members comprises two securing portions and a securing bridge connected to the two securing portions, and a distance between the securing bridge and the top plate is greater than a height of the supporting member.

8. The electronic device enclosure of claim 1, wherein the opening and the cover are substantially rectangle.

9. An electronic device enclosure comprising:
a top plate defining an opening; the top plate comprising a supporting member and a plurality of securing members around the supporting member, the supporting member located on edges of the opening and surrounding the opening; and
a cover;
wherein the cover is covered on the supporting member and secured to the plurality of securing members, to separate the opening from outdoor.

10. The electronic device enclosure of claim 9, wherein the supporting member comprises four supporting flanges substantially perpendicular to the top plate.

11. The electronic device enclosure of claim 9, wherein the opening has a first length and a first width, the opening has a second length and a second width, the second length is greater than the first length, and the second width is greater than the first width.

12. The electronic device enclosure of claim 9, further comprising a mounting gasket, and the mounting gasket is located between the supporting member and the cover.

13. The electronic device enclosure of claim 12, wherein the mounting gasket has a size greater than that of the supporting member, and the mounting gasket covers on an upper portion of the supporting member.

14. The electronic device enclosure of claim 12, wherein the mounting gasket is made of plastic.

15. The electronic device enclosure of claim 9, wherein each of the plurality of securing members comprises two securing portions and a securing bridge connected to the two securing portions, and a distance between the securing bridge and the top plate is greater than a height of the supporting member.

16. The electronic device enclosure of claim 9, wherein the opening and the cover are substantially rectangle.
